(19) United States
(12) Patent Application Publication
(10) Pub. No.: US 2009/0020068 A1
(43) Pub. Date: Jan. 22, 2009

(54) METHOD OF MANUFACTURING OF SUBSTRATE

(75) Inventor: Hiroyuki ODE, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/117,992

(22) Filed: May 9, 2008

(30) Foreign Application Priority Data
May 9, 2007 (JP) 2007-125081
May 7, 2008 (JP) 2008-121338

(51) Int. Cl. C30B 11/10

(52) U.S. Cl. 117/12

(57) ABSTRACT

A method of manufacturing a substrate is provided for readily processing a substrate in the presence of a supercritical fluid in a deposition step, an etching step, a resist peeling step and the like. The method of manufacturing a substrate of the present invention is a method of manufacturing a substrate for processing a surface of the substrate by filling a liquid fluid in a reaction chamber in which the substrate is placed, and reacting a precursor solved in the liquid fluid in the vicinity of the surface of the substrate, wherein the substrate is placed on a ceiling of the reaction chamber with the surface of the substrate oriented downward.

### SUMMARY OF THE INVENTION

This application claims the benefit of the priority based on Japanese Patent Application No. 2007-125081 filed May 9, 2007 and Japanese Patent Application No. 2008-121338 filed May 7, 2008, the disclosure of which is incorporated in their entirety by reference.

### FIELD OF THE INVENTION

The present invention relates to a method of manufacturing a substrate such as a semiconductor silicon substrate, using a reaction apparatus which employs a liquid fluid, for example, a supercritical fluid.

### DESCRIPTION OF THE RELATED ART

Generally, as processing technologies for growing a crystal film on a surface of a substrate, selectively removing a material on a surface of a substrate, and the like by reacting a precursor on a surface of a substrate, such as a semiconductor substrate, a glass substrate or the like, technologies are employed for processing a surface of a substrate by supplying a material gas itself or using a carrier gas to supply a material gas to the surface of the substrate, and activating the material gas by heat or another method for reaction on the surface of the substrate.

JP-2003-257867-A discloses a vapor phase epitaxy which uses hydrogen as a dilute gas at temperature of 700° C. and pressure of 10.1 kPa.

However, such processing methods which use a gas have increasingly cause problems in processing performance for miniature processing as represented by recent semiconductor processing. For example, when a thin film with uniform thickness is to be deposited in a recess having a diameter of approximately 200 nm on a semiconductor substrate, a material gas is not sufficiently supplied into the recess, thus failing to form the thin film with uniform thickness. This phenomenon is widely known as a micro-loading effect.

Thus, conceptions have come around to application of a supercritical fluid which exhibits behaviors and characteristics completely different from those of a gas used in the vapor phase epitaxy.

The supercritical fluid has the natures of both gas and liquid, and is known to exhibit an excellent penetration and solvency. In recent years, proposals have been made to apply the supercritical fluid having such natures to semiconductor related fields.

FIG. 1 is a schematic cross-sectional view showing apparatus 404, related to the present invention, for washing semiconductor silicon substrate 48 using a supercritical fluid.

This apparatus 404 comprises high-pressure vessel 1a which includes upper chamber 200 and lower chamber 300. Partition 44 is provided between upper chamber 200 and lower chamber 300.

This partition 44 is vertically movably arranged. By moving partition 44 upward, upper chamber 200 can be communicated with lower chamber 300. On the other hand, by moving partition 44 downward, upper chamber 200 can be isolated from lower chamber 300.

Also, upper chamber 200 is provided, on its side wall, with inflow conduit 66 for introducing a supercritical fluid into high-pressure vessel 1a, and outflow conduit 77 for discharging the supercritical fluid to the outside of high-pressure vessel 1a.

Lower chamber 300 in turn contains additive 152 for washing semiconductor silicon substrate 48.

For washing semiconductor silicon substrate 48 using this apparatus 404, semiconductor silicon substrate 48 is placed on wafer stage 46 arranged within this apparatus 404, and semiconductor silicon substrate 48 is heated by heating means provided within wafer stage 46.

The supercritical fluid, comprised of carbon dioxide, is introduced from inflow conduit 66 into upper chamber 200, and reaches from upper chamber 200 to lower chamber 300, causing additive 152 contained in lower chamber 300 to diffuse to upper chamber 200.

The diffusion of additive 152 to upper chamber 200 can be stopped by moving partition 44 downward to isolate upper chamber 200 from lower chamber 300.

In this way, this apparatus 404 related to the present invention can freely diffuse additive 152 contained in lower chamber 300 to upper chamber 200, so that it can wash semiconductor silicon substrate 48 placed in upper chamber 200 (see JP-2004-186530-A).

When an attempt was made to deposit a film using apparatus 404 related to the present invention, the inventors found that there were problems as follows. With a liquid fluid such as a supercritical fluid, completely different from a vapor phase epitaxy apparatus using a gas, heat is more likely to transmit through the supercritical fluid itself, causing a convection in the supercritical fluid within the reaction chamber. Specifically, when a semiconductor wafer is placed with its surface oriented upward, and is applied with heat by a heater from the back of the wafer, a convection occurs in the supercritical fluid, causing the heat to diffuse upward away from the wafer.

In order to limit a reaction in the vicinity of the surface of a semiconductor wafer, it is necessary to control such that a deposition temperature prevails only in the vicinity of the surface of the semiconductor wafer, but with the supercritical fluid, such control is extremely difficult due to the convection, and the temperature inevitably rises across the overall apparatus. As a result, a reaction product will be formed mainly on the ceiling of the reaction chamber. This results in lower quality of a film on the semiconductor wafer and formation of reaction products at undesirable areas within the reaction chamber, and causes a reduction in yield rate and a rise in manufacturing cost. Also, since the concentration of a dissolved precursor is sensitively changed by a change in temperature of a supercritical fluid itself, difficulties are encountered in supplying a proper amount of precursor onto the surface of the semiconductor wafer. Eventually, this also causes lower quality of film.

### SUMMARY OF THE INVENTION

It is an object of the present invention to provide a method of manufacturing a substrate, which is capable of facilitating semiconductor processes in the presence of a liquid fluid, for example, a supercritical fluid, such as a deposition step, an etching step, a resist peeling step and the like.

Diligent investigations made by the present inventors resulted in a finding that the object of the present invention is met by using a reaction apparatus which comprises means for holding a substrate on the ceiling of a high-pressure vessel, and a flow regulation plate arranged at a position in parallel with the substrate, leading to the completion of the present invention.

Specifically, a method of manufacturing a substrate of the present invention is for processing a surface of the substrate by filling a liquid fluid in a reaction chamber in which the substrate is placed, and reacting a precursor solved in the liquid fluid in the vicinity of the surface of the substrate, wherein the substrate is placed on ceiling of the reaction chamber with the surface of the substrate oriented downward.

Also, a method of manufacturing a substrate of the present invention is for processing a surface of the substrate by filling a liquid fluid in a reaction chamber in which the substrate is placed, and reacting a precursor solved in the liquid fluid in the vicinity of the surface of the substrate, wherein the substrate is placed in a direction in which heat rises due to a convection of the liquid fluid.

Also, the method of manufacturing a substrate of the present invention may heat the substrate from the back side of the substrate.

Also, the method of manufacturing a substrate of the present invention may provide heat insulation between heating means for heating the substrate and the inner wall of the reaction chamber.

Also, the method of manufacturing a substrate of the present invention may dispose a flow regulation plate at a position opposite to the surface of the substrate.

Also, the method of manufacturing a substrate of the present invention may set a gap between the surface of the substrate and the flow regulation plate to 20 mm or less.

Also, the method of manufacturing a substrate of the present invention may divide the reaction chamber into a first reaction chamber and a second reaction chamber with a flow regulation plate, where the first reaction chamber is held at the same pressure as the second reaction chamber.

Also, the method of manufacturing a substrate of the present invention may supply the liquid fluid to the second reaction chamber.

Also, the liquid fluid in the method of manufacturing a substrate of the present invention may be a supercritical fluid.

According to the present invention, a method of manufacturing a substrate can be provided, which is capable of facilitating such processes as a deposition step, an etching step, a resist peeling step and the like in the presence of a supercritical fluid.

The above and other objects, features and advantages of the present invention will become apparent from the following description with reference to the accompanying drawings which illustrate the present invention.

### BRIEF DESCRIPTION OF THE DRAWINGS

FIG. 1 is a schematic cross-sectional view showing an apparatus related to the present invention for washing a semiconductor silicon substrate using a supercritical fluid;

FIG. 2 is a schematic cross-sectional view of principal parts, illustrating a high-pressure vessel of the present invention;

FIG. 3 is a schematic cross-sectional view illustrating the opened state of a high-pressure vessel of the present invention;

FIG. 4 is a schematic cross-sectional view of principal parts, illustrating a cross section of the high-pressure vessel taken in a horizontal direction, when observed from below a reaction vessel;

FIG. 5A is a schematic perspective view of principal parts, illustrating the shape of a T-shaped pipe which is provided with supply holes arranged at regular intervals for supplying a supercritical fluid;

FIG. 5B is a schematic perspective view of principal parts, illustrating the shape of a T-shaped pipe which has a supply slit for supplying a supercritical fluid;

FIG. 6 is a schematic cross-sectional view of principal parts, illustrating a cross section of the high-pressure vessel taken in a horizontal direction, for describing the relationship between T-shaped pipe and discharge ports;

FIG. 7 is a schematic cross-sectional view of principal parts, illustrating a high-pressure vessel, which is a second embodiment of the present invention, taken in a horizontal direction;

FIG. 8 is a schematic cross-sectional view of principal parts, illustrating the high-pressure vessel, which is the second embodiment of the present invention, taken in a vertical direction;

FIG. 9 is a schematic cross-sectional view of principal parts, illustrating a high-pressure vessel which is a third embodiment of the present invention;

FIG. 10 is a schematic cross-sectional view of principal parts, illustrating a cross section of a high-pressure vessel taken in a horizontal direction, for describing the relationship between a supply port and discharge ports;

FIG. 11 is a schematic perspective view of principal parts, illustrating a substrate mounting on ceiling of the high-pressure vessel;

FIG. 12 is a schematic plan view of principal parts for describing the geometrical relationship between T-shaped pipe and 4 hooks holding a substrate;

FIG. 13 is a schematic plan view of principal parts for describing the geometrical relationship between T-shaped pipe and 3 hooks holding a substrate;

FIG. 14 a schematic plan view of principal parts for describing the geometrical relationship between a supply port and 3 hooks holding a substrate;

FIG. 15A is a schematic cross-sectional view of principal parts for describing a substrate before fixing on the heater using hooks;

FIG. 15B is a schematic cross-sectional view of principal parts for describing a substrate after fixing on the heater using hooks and

FIG. 16 is a schematic diagram of a piping network connected to a reaction apparatus.

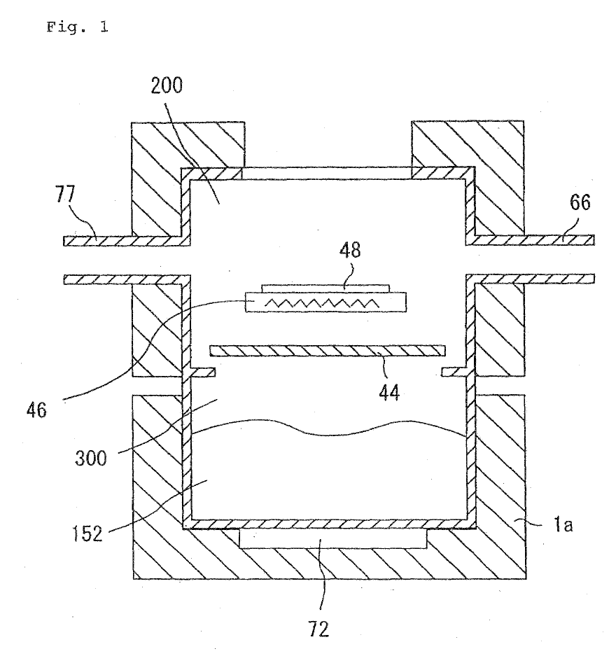

### DESCRIPTION OF PREFERRED EMBODIMENTS

In the following, embodiments of the present invention will be described with reference to the drawings.

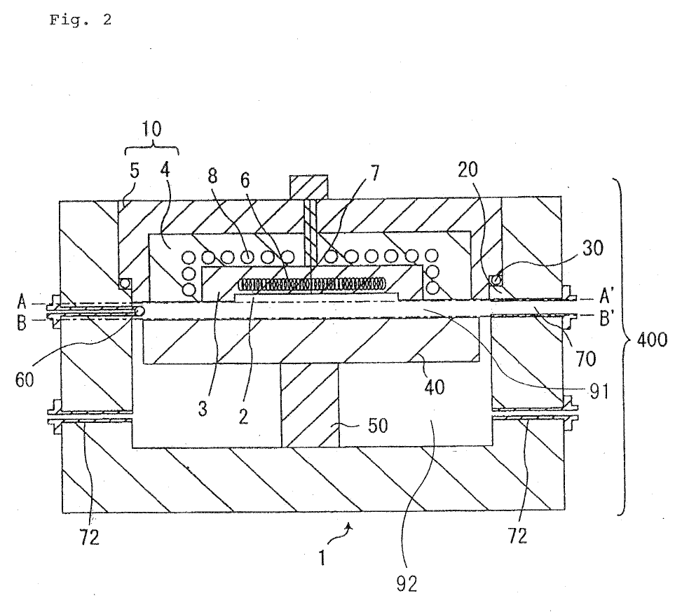

FIG. 2 is a schematic cross-sectional view of principal parts, illustrating reaction apparatus 400 which is a first embodiment of the present invention.

Reaction apparatus 400 comprises high-pressure vessel 1. First, a description will be given of high-pressure vessel 1.

High-pressure vessel 1 comprises a pressure resistant structure which can withstand sufficient pressure such that a supercritical fluid supplied into high-pressure vessel 1 can hold a supercritical state.

A material for making high-pressure vessel 1 is not limited as long as it can withstand the use of supercritical fluid, and for example, metals such as stainless steel, heat resistant inorganic materials such as ceramic, and the like is used.

The shape of high-pressure vessel 1 can be a polygonal shape such as quadrangular prism, pentagonal prism, hexagonal prism, or the like, a cylindrical shape, a spherical shape, and the like. In this regard, the shape of high-pressure vessel 1 is preferably a cylindrical shape from an aspect of handling ease.

This high-pressure vessel 1 is also provided with opening/closing means, and ceiling 10 of high-pressure vessel 1 is structured to be freely movable up and down.

Ceiling part 10 comprises a pedestal 3 for placing a substrate, which has an area 2 for mounting a substrate therein; and a ceiling frame 5 arranged to surround a heat insulator 4, and is made of metal, for example, stainless steel or the like. A substrate is placed on the pedestal 3 with its surface oriented downward. Alternatively, the substrate is placed in a direction in which heat rises due to a convection in the supercritical fluid.

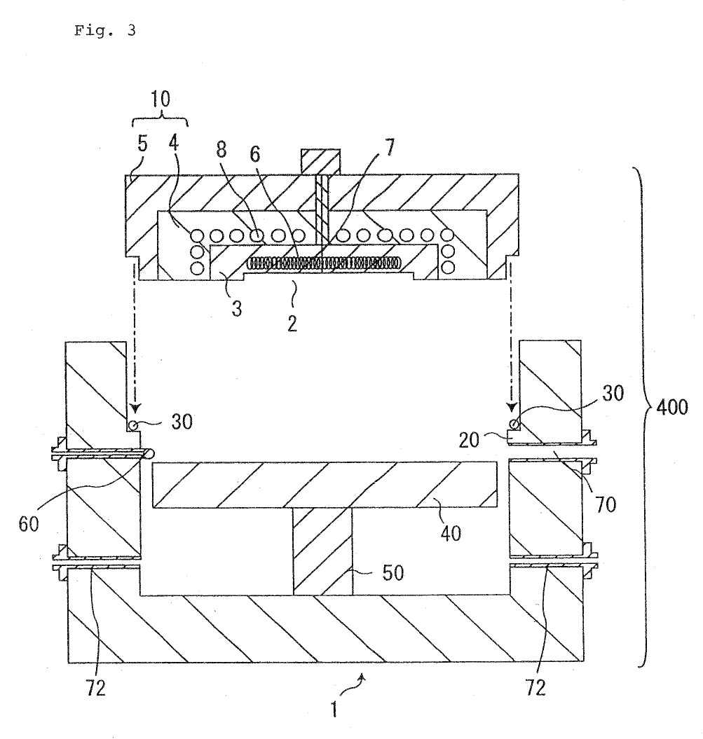

FIG. 3 is a schematic cross-sectional view illustrating the opened state of the high-pressure vessel 1.

The high-pressure vessel 1 is provided with cylindrical protrusion 20 formed inside thereof. When ceiling 10 is moved downward, an end of ceiling frame 5 comes into contact with the protrusion 20, thereby preventing ceiling 10 from moving downward more than necessary.

Also, elastic ring material 30 made of fluorinated resin or the like is disposed between the end of ceiling frame 5 and protrusion 20, so that a gap between the end of ceiling frame 5 and the protrusion 20 can be completely sealed.

Moving means (not shown), which makes use of hydraulic pressure or the like, is provided above ceiling 10 and can move up and down ceiling 10.

When high-pressure vessel 1 is hermetically closed, the moving means functions as means for fixing ceiling 10 on the body of high-pressure vessel 1, so that ceiling 10 can be prevented from inadvertently opening when reaction apparatus 400 is in use.

Turning back to FIG. 2, the structure of ceiling 10 will be described in detail.

Heating means such as electric heater 6 or the like is contained within pedestal 3 of FIG. 2. By supplying electric power to electric heater 6 through heater wire 7, a substrate can be heated when the substrate is placed on the pedestal 3.

The temperature of the substrate can be controlled by supplying electric power to electric heater 6 and stopping supplying electric power. Cooling pipe 8 is also provided in heat insulator 4. This cooling pipe 8 functions as cooling means for preventing heat from diffusing to regions other than pedestal 3 for placing a substrate, i.e., the ceiling 10, the main body of high-pressure vessel 1, and the like, by circulating therethrough a cooling medium such as water or the like.

Together with heater wire 7, a temperature detecting means, in the form of a thermocouple wire, is provided and can detect the temperature of a substrate (not shown).

By controlling this temperature detecting means and heating means such as electric heater 6 in association, a substrate can be held at a constant temperature. Further, in addition to these, the temperature may be controlled in association with the cooling means implemented by cooling pipe 8.

On the other hand, pedestal 3 is provided with mechanically fixing means such as a hook (not shown) such that a substrate can be fixed on an area 2 of the pedestal 3.

Means for fixing a substrate on pedestal 3 is not limited to the mechanically fixing means, but in addition to the mechanically fixing means or instead of the mechanically fixing means, one or two or more may be employed, for example, from decompression fixing means for fixing a substrate on pedestal 3 by reducing pressure in a portion closely contact with the substrate, and electrostatic fixing means for fixing a substrate on pedestal 3 by making use of static electricity.

Next, a description will be given of the body of high-pressure vessel 1.

As illustrated in FIG. 2, a flow regulation plate 40 is disposed within high-pressure vessel 1 by way of supporting shaft 50.

Flow regulation plate 40 is disposed at a position at which a substrate and flow regulation plate 40 oppose in parallel with each other, when the substrate is placed on pedestal 3.

Generally, a substrate placed on pedestal 3 and flow regulation plate 40 are arranged in a horizontal direction.

When pedestal 3 is obliquely arranged on ceiling 10, flow regulation plate 40 is also obliquely disposed in correspondence thereto. In this way, when a substrate is placed on pedestal 3, the substrate and flow regulation plate 40 are opposed in parallel with each other.

By thus opposing a substrate and flow regulation plate 40 in parallel with each other, a supercritical fluid can be smoothly supplied into a gap between the substrate placed in pedestal 3 and flow regulation plate 40.

The distance between the surface of a substrate and flow regulation plate 40 is set as appropriate in accordance with the size of the substrate used in the high-pressure vessel of the present invention. Reaction apparatus of the present invention (FIG. 16) heats the substrate with electric heater 6 disposed above the substrate, fills the reaction chamber with a supercritical fluid, and supplies a precursor dissolved in the supercritical fluid. In the reaction chamber during the reaction, the temperature of the supercritical fluid becomes lower as it is further away from the surface of the substrate. Lowering temperature of the supercritical fluid accompanies the increasing of precursor density. As a result, the concentration of the precursor tends to be higher in a region further away from the surface of the substrate. The precursor diffusing away from the substrate surface due to the fluid density gradient simply passes through the reaction chamber without contributing to the reaction, resulting in a large amount of waste of the precursor. Thus, by disposing flow regulation plate 40 in close proximity to the surface of the substrate, the precursor wastefully discharged can be minimized.

On the other hand, it is necessary to prevent a reaction product from occurring on the surface of flow regulation plate 40 during the reaction. A temperature gradient in a direction away from the surface of the substrate is not abrupt as is the case with a gas, but slow with the supercritical fluid. For this reason, if the distance is too short between flow regulation plate 40 and the surface of the substrate, the temperature on the surface of flow regulation plate 40 will reach the reaction temperature, causing the reaction product on the surface of flow regulation plate 40. Accordingly, the distance between flow regulation plate 40 and the surface of the substrate is set such that the temperature on the surface of flow regulation plate 40 falls below the reaction temperature.

Consequently, a range of 1 mm to 20 mm is preferable when a substrate is a semiconductor silicon wafer having a diameter of 300 mm, and a range of 3 mm to 10 mm is more preferable. The distance more than 20 mm between the surface of the substrate and flow regulation plate 40 is not preferable because this causes an increase in the precursor which does not contribute to the reaction. Also, the distance less than 1 mm between the surface of the substrate and flow regulation plate 40 is not either preferable because a reaction product occurs on the surface of flow regulation plate 40.

Also, in flow regulation plate 40, an area of flow regulation plate 40 superimposing over the ceiling within high-pressure vessel 1 at least has an area which cover the entirety of a ceiling area for placing a substrate. The area superimposing over the ceiling within high-pressure vessel 1 refers to a projected image of flow regulation plate 40 to a Diane represented by one-dot broken line A-A′ in FIG. 2. The ceiling area for placing a substrate refers to a projected image of area 2 for placing the substrate.

FIG. 4 is a schematic cross-sectional view of principal parts, illustrating a cross section of high-pressure vessel 1 taken along one-dot broken line A-A′ shown in FIG. 2, as observed from below high-pressure vessel 1.

While the position of flow regulation plate 40 is indicated by a broken line in FIG. 4, a projected image of flow regulation plate 40 covers a projected image of the area 2 for placing a substrate, as illustrated in FIG. 4.

In this way, by setting the area of flow regulation plate 40 to the area 2 or more, a supercritical fluid can be smoothly supplied into the gap between a substrate placed on mount 3 and flow regulation plate 40.

The area of flow regulation plate 40 is preferably in a range of 100% to 400% with respect to the area 2, and more preferably in a range of 110% to 200%.

While the shape of flow regulation plate 40 is selected as appropriate in conformity to the shape of a substrate used in high-pressure vessel 400 of the present invention, the shape of flow regulation plate 40 is preferably in the same shape as or in a similar shape to the shape of a processed surface of a substrate.

Flow regulation plate 40 is made, for example, of metal such as stainless steel or the like, and its surface is smooth and uniform. The top surface is preferably mirror finished.

Flow regulation plate 40 used herein may be a metal plate such as stainless steel, the surface of which is covered with fluorinated resin or the like.

Also, flow regulation plate 40 is different from one for dividing the reaction chamber into respective hermetically sealed partitions, such as a diaphragm, a partition or the like which is generally disposed within a high-pressure vessel, and respective partitions of the reaction vessel divided by flow regulation plate 40 communicate with each other. Specifically, flow regulation plate 40 divides the reaction chamber into first reaction chamber 91 and second reaction chamber 92, and communicates between these two chambers. Thus, when a supercritical fluid is supplied into the reaction vessel, the supercritical fluid can freely move between first reaction chamber 91 and second reaction chamber 92. In this regard, first reaction chamber 91 is a space sandwiched by flow regulation plate 40 and ceiling 10, while second reaction chamber 92 is a space sandwiched by flow regulation plate 40 and the bottom of high-pressure vessel 1.

Next, a description will be given of supply means for supplying a supercritical fluid into high-pressure vessel 1, and discharge means for discharging the supercritical fluid to the outside of high-pressure vessel 1.

As illustrated in FIG. 2, T-shaped pipe 60 connected to an inlet-port of the body of high-pressure vessel 1 is provided through a side wall of high-pressure vessel 1.

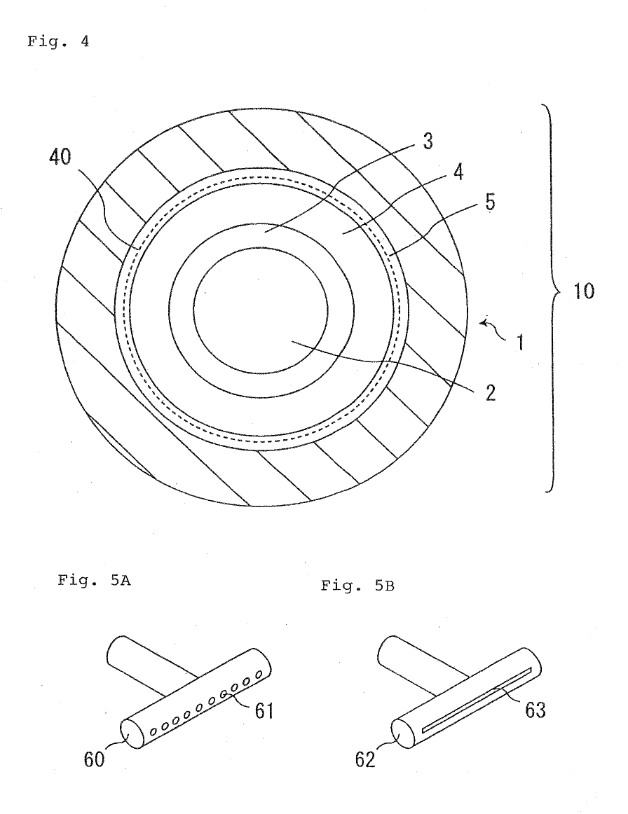

FIGS. 5A and 5B are schematic perspective views of principal parts, illustrating the shape of T-shaped pipe 60.

As illustrated in FIG. 5A, T-shaped pipe 60 used in the apparatus of the present invention is provided with supply holes 61 arranged at regular intervals for supplying a supercritical fluid.

Alternatively, the supply hole provided in the T-shaped pipe may have a slit-like shape, like supply slit 63 of T-shaped pipe 62 shown in FIG. 5B.

Supply holes 61 and slit 63 are preferably positioned on a straight line parallel with the top surface of the flow regulation plate.

As illustrated in FIG. 2, by supplying a supercritical fluid to supply holes 61 (see FIG. 5) through T-shaped pipe 60 from an external pipe (not shown), the supercritical fluid can be supplied into high-pressure vessel 1.

Also, as illustrated in FIG. 2, supply holes 61 (see FIG. 5) are disposed at a position below a plane which passes the ceiling within high-pressure vessel 1 (plane represented by one-dot broken line A-A′ in FIG. 2) and at a position above the top of flow regulation plate 40 (plane represented by one-dot broken line B-B′).

By disposing supply holes 61 at that position, a supercritical fluid can be smoothly supplied into the gap between a substrate placed in area 2 the flow regulation plate.

On the other hand, supercritical fluid discharge ports 70 are disposed through a side wall of high-pressure vessel 1 at a position opposite to T-shaped pipe 60.

The total cross-sectional area of a plurality of discharge ports 70 has a size equal to or larger than the total cross-sectional area of supply holes 61, so that the supercritical fluid supplied into high-pressure vessel 1 from supply ports 61 can be smoothly discharged to the outside of high-pressure vessel 1.

For smoothly discharging the supercritical fluid to the outside of high-pressure vessel 1, discharge ports 70 are preferably disposed on a straight line parallel with the top surface of the flow regulation plate.

Also, as illustrated in FIG. 2, discharge ports 70 are disposed at a position below the plane which passes the ceiling within high-pressure vessel 1 (plane represented by one-dot broken line A-A′ in FIG. 2) and at a position above the top surface of flow regulation plate 40 (plane represented by one-dot broken line B-B′).

By disposing discharge ports 70 at that position, the supercritical fluid supplied into the gap between a substrate placed on pedestal 3 and flow regulation plate 40 can be smoothly discharged to the outside.

FIG. 6 is a schematic cross-sectional view of principal parts, illustrating a cross section of high-pressure vessel 1 taken in a horizontal direction, for describing the relationship between T-shaped pipe 60 and discharge ports 70. For convenience of description, flow regulation plate 40 is indicated by a broken line.

As illustrated in FIG. 6, high-pressure chamber 1 comprises two or more discharge ports 70.

Also, discharge ports 70 are arranged at equal intervals at positions at which a plane parallel with the top surface of flow regulation plate 40 intersects with a side wall of high-pressure vessel 1.

Supply ports 61 and discharge ports 70 are disposed on a plane parallel with the top surface of flow regulation plate 40, so that a supercritical fluid supplied into high-pressure vessel 1 from supply ports 61 is smoothly discharged to the outside from discharge ports 70.

In this regard, as illustrated in FIG. 2, supply/discharge ports 72 are disposed through side walls in a lower region of high-pressure vessel 1, so that a necessary reagent or the like can be supplied from supply/discharge ports 72, and a surplus supercritical fluid can be discharged to the outside.

Next, a description will be given of reaction apparatus 401 which is a second embodiment of the present invention.

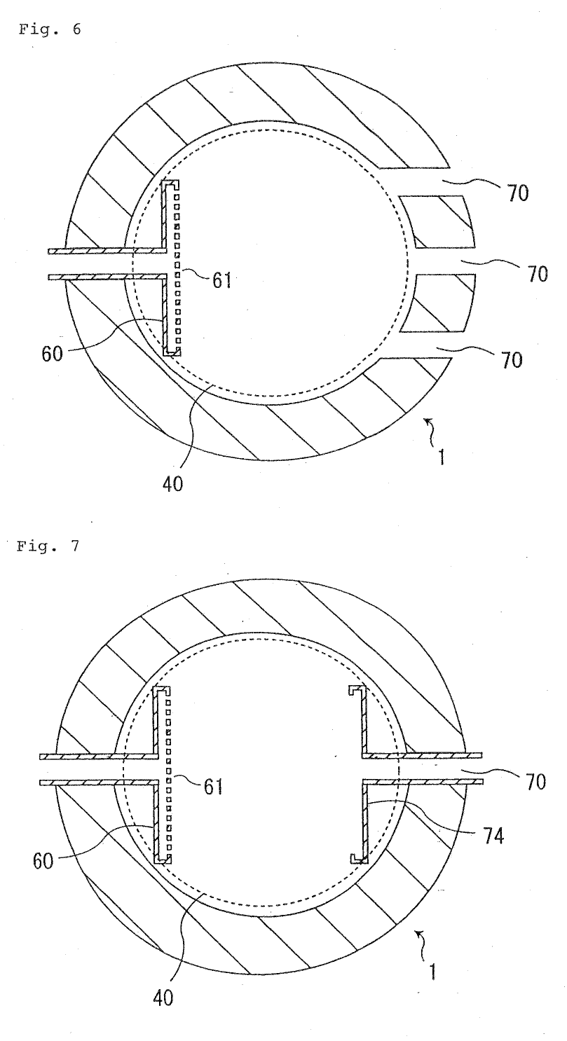

FIG. 7 is a schematic cross-sectional view of principal parts, illustrating reaction apparatus 401, which is the second embodiment of the present invention, taken in a horizontal direction.

Previous reaction apparatus 400 which is the first embodiment has discharge ports 70 directly extended through the side wall of high-pressure vessel 1. In contrast, reaction apparatus 401 of the second embodiment differs from reaction apparatus 400 in that discharge port 70 is provided on a side wall of high-pressure vessel 1 through T-shaped pipe 74.

The shape of T-shaped pipe 74 is similar to T-shaped pipe 62 illustrated in FIG. 5.

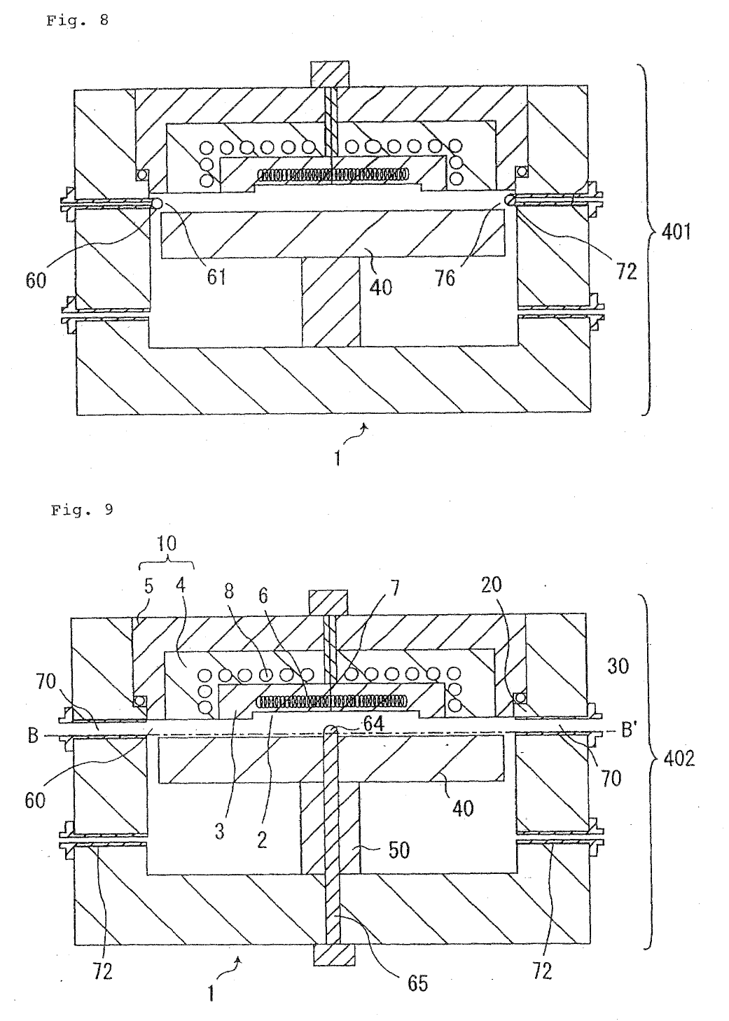

FIG. 8 is a schematic cross-sectional view of principal parts, illustrating reaction apparatus 401, which is the second embodiment of the present invention, taken in a vertical direction.

As illustrated in FIG. 8, T-shaped pipe 60 and T-shaped pipe 74 are disposed on a plane parallel with the top surface of flow regulation plate 40, and supply T-shaped pipe 60 and discharge T-shaped pipe 74 are disposed at positions opposite to and parallel with each other.

Next, a description will be given of reaction apparatus 402 which is a third embodiment of the present invention.

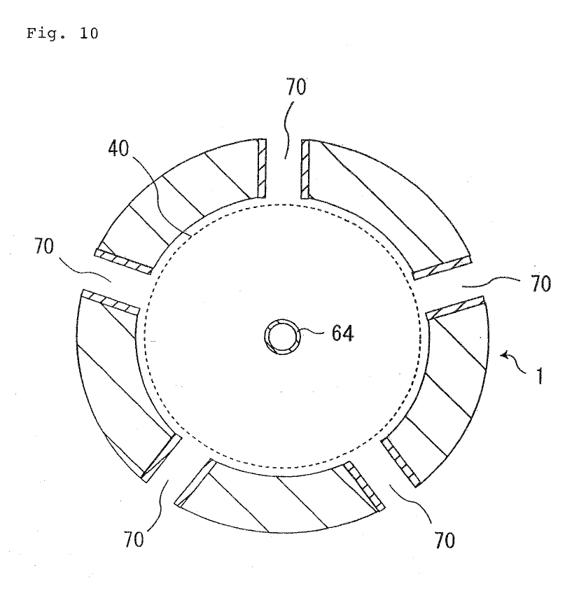

FIG. 9 is a schematic cross-sectional view of principal parts, illustrating reaction apparatus 402 which is the third embodiment of the present invention.

Previous reaction apparatus 400 of the first embodiment and reaction apparatus 401 of the second embodiment are structured such that supply holes 61 are made on T-shaped pipe 60 connected to the throughhole in the side wall of high-pressure vessel 1. In contrast, reaction apparatus 402 of the third embodiment differs in that supply port 64 is disposed at the center of flow regulation plate 40 vertically in opposition to the ceiling.

The shape of flow regulation plate 40 is discoid, and supercritical fluid supply pipe 65 is disposed at the center thereof.

By supplying a supercritical fluid to supply port 64 through supply pipe 65 from an external pipe (not shown), the supercritical fluid can be supplied into high-pressure vessel 1.

In this regard, supply port 64 is preferably in the shape of a shower head, the leading end of which is in hemispherical and provided with a plurality of holes.

FIG. 10 is a schematic cross-sectional view of principal parts, illustrating a cross section of high-pressure vessel 1 taken in a horizontal direction, for describing the relationship between the supply port and the discharge ports. For convenience of description, flow regulation plate 40 is indicated by a broken line.

Reaction apparatus 402 of the third embodiment can radially supply a supercritical fluid into a gap between a substrate placed on pedestal 3 and flow regulation plate 40 from supply port 64 disposed at the center of flow regulation plate 40.

On the other hand, high-pressure vessel 1 is provided with two or more discharge ports 70.

Discharge ports 70 are arranged at equal intervals at positions at which a plane parallel with the top surface of flow regulation plate 40, i.e., a plane represented by one-dot broken line B-B′ in FIG. 9 intersects with the side wall of high-pressure vessel 1.

Also, as illustrated in FIG. 10, when high-pressure vessel 1 is, for example, in a cylindrical shape, and five discharge ports 70 are disposed through the side wall of high-pressure vessel 1, each discharge port 70 is preferably disposed at an equal angle of 72 degrees from the center of the flow regulation plate.

Likewise, when n discharge ports are disposed, each discharge port is preferably disposed at an equal angle of 360/n degrees from the center of flow regulation plate 40.

Next, a description will be given of a substrate which is used in the reaction apparatus of the present invention.

A substrate used in the reaction apparatus of the present invention may be, for example, a semiconductor silicon wafer for use in semiconductor applications, a processed substrate fabricated using a semiconductor silicon wafer through a variety of steps for forming semiconductor elements on the silicon wafer, and the like.

FIG. 11 is a schematic perspective view of principal parts, illustrating substrate 42 mounted on area 2 of the present invention. For convenience of description, FIG. 11 shows parts related to ceiling 10 of reaction apparatus 402 and the like, and does not show the flow regulation plate and the like.

When the high-pressure vessel of the present invention is used, substrate 42 is placed on area 2 as illustrated in FIG. 11, with a surface subjected to processing oriented downward. As previously described, ceiling 10 of the reaction apparatus is provided with hooks 12 for fixing substrate 42, so that high-pressure vessel 402 can be used while substrate 42 under processing remains fixed on ceiling 10.

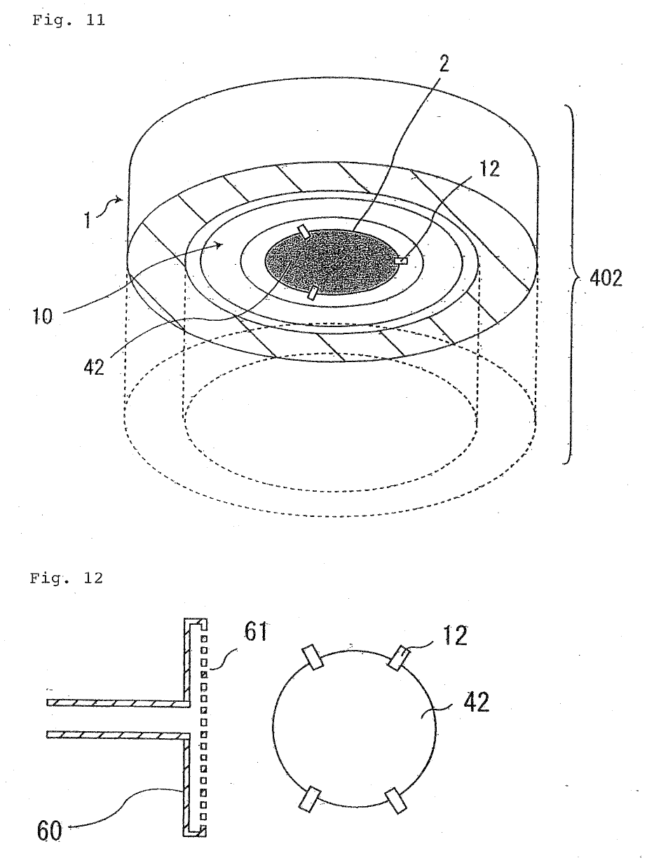

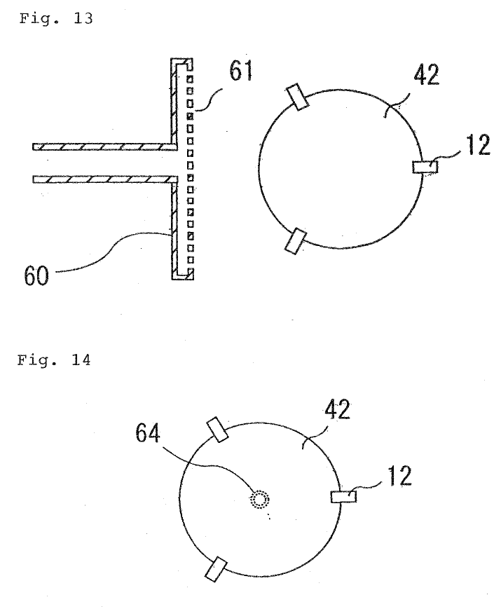

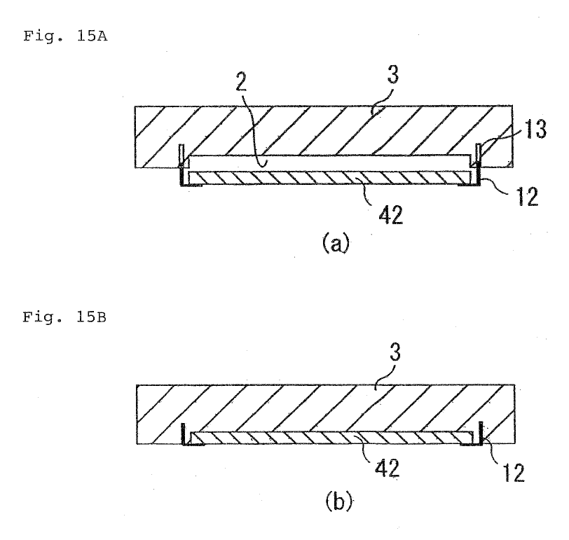

FIGS. 12 to 14 are schematic plan views of principal parts for describing the geometrical relationship between T-shaped pipe 60 (supply port 64 in FIG. 14) and the hooks holding substrate 42.

As illustrated in FIGS. 12 to 14, a plurality of hooks 12 are provided for fixing substrate 42 under processing. Also, hooks 12 are preferably disposed at symmetric positions with respect to the center of flow regulation plate 40 so as not to prevent the flow of the supercritical fluid from supply port 61 disposed in T-shaped pipe 60, and the supercritical fluid from supply port 64 disposed at the center of flow regulation plate 40.

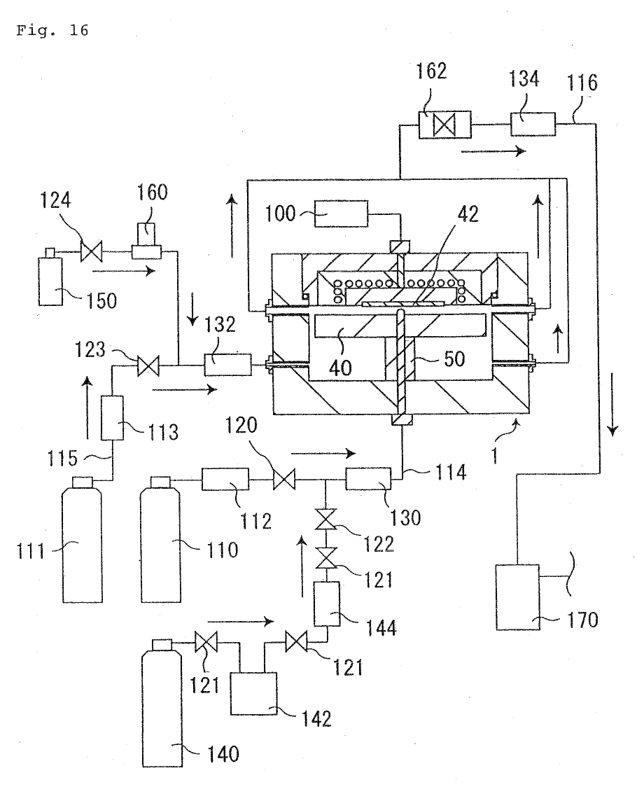

FIGS. 15A and 15B are schematic cross-sectional views of principal parts for describing operations for fixing substrate 42 on pedestal 3 using the hooks.

As illustrated in FIGS. 15A and 15B, hooks 12 used herein can be L-shaped ones.

By inserting hooks 12 into hook holes 13 provided in pedestal 3, substrate 42 can be fixed on pedestal 3.

In this regard, portions of hooks 12 which is in contact with substrate 42 in parallel are preferably in planar shape so as not to prevent the flow of a supercritical fluid.

Next, a description will be given of a supercritical fluid used in the reaction apparatus of the present invention.

While there are no particular limitations to the supercritical fluid used in the reaction apparatus of the present invention, specifically, water, carbon dioxide and the like which

exhibit a supercritical state under conditions of pressure and temperature equal to or higher than the critical points. One or two types of supercritical fluids can be used in the reaction apparatus of the present invention.

Also, the supercritical fluid can contain one or two types of washing reagent, etching reagent, precursor for deposition, resist peeling reagent, and the like.

Washing reagents may be, for example, chelating agents such as hexafluoroacetylacetonate, acetylacetone, ethyl acetoacetate, dimethyl maleate, 1,1,1-trifluoropentane-2,4-dione, 2,6-dimethylpentanedione-3,5-dione, 2,2,7-trimethyloctane-2,4-dione, 2,2,6,6-tetramethylheptane-3,5-dione, ethyleneethylene diamine tetra-ace, and the like;

organic acids such as formic acid, acetic acid, oxalic acid, maleic acid, nitrilotriacetic acid, and the like;

inorganic acids such as hydrogen chloride, hydrogen fluoride, phosphor acid, and the like;

nitrogen containing compounds such as annomina, ethanolamine, and the like;

alcohol groups such as ethanol and the like; and

surface active agents such as perfluoropolyether (PFPE) and the like.

Etching reagents may be, for example, hydrofluoric acid, and the like.

Precursors for deposition may be, for example, metal chelate compound groups such as bis(ethylcyclopentadienil) ruthenium, tris(2,4-octadionite) ruthenium, pentaquis(dimethylamino) tantalum, pentaethoxytantalum, tetra-t-butoxytitanium, tetraquis(N-ethyl-N-methylamino) titanium, iridium acetylacetone, platinum acetylacetone, and the like;

silicon compound groups such as tetrachlorosilane, tetramethoxysilane, tetraethoxysilane, and the like; and

oxygen, ozone, hydrogen, nitrogen, ammonia, water and the like which react with metal chelate compounds to produce metal.

Resist peeling reagents may be, for example, alcohol groups such as methanol, ethanol, propanol, and the like.

Also, the temperature and pressure are as follows when the reaction apparatus of the present invention is used.

While the temperature and pressure when the reaction apparatus of the present invention is used depend on the type of supercritical fluid used in the reaction apparatus, the temperature is preferably in a range of 31° C. to 350° C., and more preferably in a range of 40° C. to 300° C., for example, when carbon dioxide is used. The pressure in turn is preferably in a range of 9 MPa to 20 MPa.

Incidentally, when a supercritical fluid is supplied into a general high-pressure vessel, a convection may occur to cause a higher temperature region and a lower temperature region to exist within the supercritical fluid within the high-pressure vessel.

When a higher temperature region and a lower temperature region exist in a supercritical fluid within a high-pressure vessel, the higher temperature region of the supercritical fluid tends to be in an upper part within the high-pressure vessel, while the lower temperature region of the supercritical fluid tends to be in a lower part within the high-pressure vessel, as is the case with a general liquid or gas. For this reason, a reaction product is mainly formed on the ceiling side of the reaction chamber.

From the fact that the reaction apparatus of the present invention has a structure which permits a substrate to be placed on the ceiling within the high-pressure vessel, and the heating means for the substrate is installed in the ceiling within the high-pressure vessel, the reaction apparatus of the present invention has a structure which promotes the heated supercritical fluid to stay in the vicinity of the substrate.

Accordingly, the reaction apparatus of the present invention is characterized by the ease of temperature control for the supercritical fluid in contact with a placed substrate.

On the other hand, the supercritical fluid has a property that its density largely fluctuates in response to a change in temperature.

The density of the supercritical fluid increases as its temperature slightly decreases. As such, the supercritical fluid, the temperature of which decreases, tends to move downward within the high-pressure vessel. In addition, the supercritical fluid which increases in density tends to exhibit larger solubilities of a washing reagent, an etching reagent, a precursor for deposition, and the like.

Due to these effects, a washing reagent, an etching reagent, a precursor for deposition or the like, introduced into the high-pressure vessel often concentrates in a lower part within the high-pressure vessel, so that it is difficult to supply a constant amount of the washing reagent, etching reagent, precursor for deposition or the like to the surface of a substrate simply by placing the substrate on the ceiling within the high-pressure vessel.

In respect to this aspect, the reaction apparatus of the present invention comprises the previously described flow regulation plate disposed in close proximity to the ceiling within the high-pressure vessel, and has a structure which permits a supercritical fluid to be supplied between the ceiling and the flow regulation plate within the high-pressure vessel, thus making it easy to supply a constant amount of washing reagent, etching reagent, precursor for deposition, or the like to the surface of a substrate.

On the other hand, as described above, while the flow regulation plate must be disposed in close proximity to the ceiling within the high-pressure vessel, a reaction using a supercritical fluid inherently requires high pressure, so that the side wall of the reaction apparatus is loaded with higher pressure. For this reason, the present invention provides the second reaction chamber below the flow regulation plate to mitigate the pressure load on the side wall of the reaction apparatus. In this regard, the supercritical fluid is supplied to the second reaction chamber from the outside in order to prevent a precursor from leaking into the second reaction chamber.

The reaction apparatus of the present invention is also characterized in that residual components and the like caused by reactions and the like seldom remain on the surface of a substrate because the supercritical fluid supplied from the supply port provided within the high-pressure vessel is unidirectionally discharged toward the discharge ports beyond the surface of the substrate.

In this way, the reaction apparatus of the present invention restrains a convection and a turbulent flow of a supercritical fluid from occurring in the vicinity of the surface of a substrate. Consequently, from the fact that residual components and the like produced by reactions and the like are unlikely to stick to the surface of the substrate, the reaction apparatus of the present invention can provide a highly pure processed substrate.

Next, the present invention will be described in greater details with reference to examples, but the present invention is not at all limited by these examples.

### Example 1

FIG. 16 is a schematic diagram of a piping network connected to reaction apparatus 403.

The structure of reaction apparatus 403 described in this example is similar to the structure of reaction apparatus 402 of the third embodiment previously described with reference to FIGS. 9 and 10.

With reaction apparatus 403, a substrate such as a semiconductor silicon wafer of 300-mm diameter or the like can undergo a washing step, an etching step, a deposition step, a resist peeling step, and the like.

High-pressure vessel 1 included in reaction apparatus 403 is made of 316 stainless steel in a cylindrical shape, and 106 mm or more of thickness is ensured therefor even in the thinnest part. The outer diameter of high-pressure vessel 1 is 712 mm. Also, the height inside of high-pressure vessel 1 from the bottom to the ceiling is 300 mm, and the volume within high-pressure vessel 1 is approximately 60 L.

Flow regulation plate 40 made of 316 stainless steel is also disposed within high-pressure vessel 1, and the gap between the ceiling and flow regulation plate 40 within high-pressure vessel 1 is set to 5 mm.

Supporting shaft 50 made of 316 stainless steel is disposed downward from the center of flow regulation plate 40, and can dispose flow regulation plate 40 at a predetermined position within high-pressure vessel 1. The distance from the ceiling to flow regulation plate 40 within high-pressure vessel 1 can be adjusted as appropriate by changing the length of supporting shaft 50.

Substrate 42 under processing is fixed by mechanical fixing means (not shown) such as hooks on the ceiling within high-pressure vessel 1.

Also, heating means such as a heater and temperature detecting means such as a thermocouple are contained in pedestal 3 holding substrate 42, so that substrate 42 under processing can be held at a constant temperature by temperature controller 100 which automatically conducts, using a computer program, operations for powering the heater to heat the substrate when its temperature is low, and turning the heater off to interrupt the heating when the substrate is at high temperatures.

Also, a cooling circulation water pipe is separately provided above the heater, such that heat can be prevented from diffusing to regions other than the area for placing a substrate, i.e., the ceiling, the body of the high-pressure vessel, and the like.

Also, carbon dioxide can be supplied to heat exchanger 130 by carbon dioxide supply pump 112 from separately prepared liquid carbon dioxide cylinder 110 through pressure valve 120. Heated carbon dioxide is supplied into high-pressure vessel 1 by this heat exchanger 130 in a supercritical state.

The carbon dioxide in the supercritical state passes through a pipe provided within supporting shaft 50, and is unidirectionally and uniformly supplied to the gap between the surface of substrate 42 under processing and flow regulation plate 40 through a supply port in the shape of shower head.

The amount of supplied carbon dioxide in the supercritical state is preferably in a range of 0.1 L/minute to 3.5 L/minute.

On the other hand, a reagent supply pipe is separately coupled to carbon dioxide supply pipe 114 which reaches heat exchanger 130, so that a reagent mixed with the carbon dioxide in the supercritical state can be supplied into reaction apparatus 403.

Specifically, nitrogen can be introduced into reagent storage vessel 142 from nitrogen cylinder 140 through pressure valve 121. By pushing out a reagent within reagent storage vessel 142 by the nitrogen supplied from nitrogen cylinder 140, the reagent can be introduced into carbon dioxide supply pipe 114 through reagent pump 144, pressure valve 121, and check valve 122.

Also, a reaction gas can be introduced into high-pressure vessel 1.

Another carbon dioxide supply pipe 115 has been prepared for supplying carbon dioxide to heat exchanger 132 from separately prepared liquid carbon dioxide cylinder 111 through pressure valve 123 by carbon dioxide supply pump 113, such that a reaction gas can be introduced into this carbon dioxide supply pipe 115 from reaction gas cylinder 150 through pressure valve 124 and mass flow controller 160.

The introduced reaction gas is mixed with carbon dioxide, and introduced into heat exchanger 132. The carbon dioxide including the reaction gas heated by this heat exchanger 132 is supplied into high-pressure vessel 1 in the supercritical state.

In this way, reaction apparatus 403 of the present invention comprises carbon dioxide supply means, liquid reagent supply means, and reaction gas supply means, but the reaction apparatus of the present invention may comprise one supply means of the liquid reagent supply means and reaction gas supply means.

The carbon dioxide in the supercritical state introduced into high-pressure vessel 1 is recovered into recovery vessel 170 from the discharge port shown in FIG. 16 through discharge pipe 116 and back pressure regulator 162, and by way of heat exchanger 134.

After the carbon dioxide in the supercritical state has been supplied into high-pressure vessel 1, substrate 42 under processing is heated to a constant temperature.

Subsequently, substrate 42 under processing can be uniformly and highly purely reacted by supplying at least one of a liquid reagent or a reaction gas into high-pressure vessel 1.

After the reaction, the supply of the liquid reagent and reaction gas is stopped, followed by supplying pure carbon dioxide in the supercritical state, to replace the liquid reagent and reaction gas within high-pressure vessel 1 with the pure carbon dioxide in the supercritical state.

Subsequently, a processed substrate can be provided by returning the interior of high-pressure vessel 1 to a room temperature and an atmospheric pressure.

### Example 2

A description will be given of a method of manufacturing the processed substrate using reaction apparatus 403 described in Example 1.

Specifically, giving an example, where a semiconductor silicon wafer of 300-mm diameter is used as a substrate, a description will be given of a step of depositing a silicon oxide film on the surface of this substrate.

First, in a manner similar to Example 1, substrate 42 is fixed on the ceiling within high-pressure vessel 1 by mechanically fixing means such as hooks or the like.

Next, carbon dioxide in a supercritical state is supplied from carbon dioxide supply pipe 114 in FIG. 16 into high-pressure vessel 1.

The pressure within high-pressure vessel 1 is adjusted at 12 MPa, so that carbon dioxide within high-pressure vessel 1 can be held in the supercritical state. By supplying the high-pressure vessel 1 with the carbon dioxide in the supercritical state, the carbon dioxide in the supercritical state is completely substituted within high-pressure vessel 1.

Next, substrate 42 under processing is heated by powering an electric heater, and the temperature of substrate 42 under processing is heated to 200° C.

On the other hand, TEOS (tetraethoxysilane) previously filled in reagent storage vessel 142 is compressively sent to reagent pump 144 by a nitrogen gas. Then, from this reagent pump 144, TEOS is supplied into high-pressure vessel 1 through carbon dioxide supply pipe 114.

Since TEOS is soluble in the carbon dioxide in the supercritical state, TEOS is actually supplied into high-pressure vessel 1 as a carbon dioxide solution in the supercritical state.

The carbon dioxide solution of TEOS in the supercritical state passes through a pipe provided within supporting shaft 50, and is unidirectionally, and uniformly supplied to the gap between the surface of substrate 42 under processing and flow regulation plate 40 through a supply port in the shape of shower head.

The gap between the surface of substrate 42 under processing and flow regulation plate 40 is 5 mm, and a radial, unidirectional, and uniform flow of the carbon dioxide solution of TEOS in the supercritical state occurs in this narrow gap.

In this way, a two-dimensional flow adjusted to such an extent that a vertical convection can be sufficiently ignored can be created within high-pressure vessel 1.

The carbon dioxide solution of TEOS in the supercritical state is discharged to the outside through a plurality of discharge ports disposed through the side wall of high-pressure vessel 1.

As described above, reaction apparatus 403 of the present invention can efficiently and uniformly supply TEOS to substrate 42 under processing.

On the other hand, oxygen, which is a reaction gas required to polymerize TEOS to deposit a silicon oxide on the surface of substrate 42 under processing, is supplied from reaction gas cylinder 150.

The oxygen supplied from reaction gas cylinder 150 is supplied to carbon dioxide supply pipe 115 after its flow rate has been adjusted by mass flow controller 160. The oxygen dissolves in the carbon dioxide in the supercritical state, and is supplied into high-pressure vessel 1.

TEOS and oxygen are reacted on the surface of substrate 42 under processing, thereby resulting in the formation of a silicon oxide film on the surface of substrate 42 under processing.

Also, surplus component such as carbon produced by the polymerization of TEOS dissolves in the carbon dioxide in the supercritical state and is smoothly discharged from the discharge ports to the outside, so that the surplus components such as carbon are extremely rarely taken into the silicon oxide film formed on substrate 42 under processing, thus making it possible to form a highly pure silicon oxide film on substrate 42 under processing.

The silicon oxide film produced on the processed substrate by the foregoing step is uniform and has a film quality with strength.

While this example has been described above giving an example where TEOS is used, a reagent used in the reaction apparatus of the present invention is not limited to TEOS, TEOS can be changed to another reagent as appropriate for use.

With a reagent other than TEOS, by performing the foregoing operations in a similar manner, a substrate can undergo such steps as washing, etching, deposition, resist peeling and the like.

The reaction apparatus of the present invention, because of its simple structure, excels in cost efficiency, mass-productivity, reliability and the like, as compared with reaction apparatuses having complicated configuration, and even if any trouble occurs in the reaction apparatus of the present invention, any part can be readily replaced, so that it also excels in maintenance management.

Moreover, from the fact that a processed substrate manufactured by this apparatus excels in purity, uniformity and the like, the reaction apparatus of the present invention can be used particularly usefully in applications which treat a process of manufacturing a semiconductor silicon substrate, particularly in applications which treat a process of manufacturing a semiconductor device such as DRAM (Dynamic Random Access Memory) and the like.

While the foregoing examples have been described using a supercritical fluid as an example of a liquid fluid, the present invention is not so limited.

While preferred embodiments of the present invention have been presented and described in detail, it should be understood that a variety of changes and modifications can be made without departing from the spirit or scope of the appended claims.

1. A method of manufacturing a substrate for processing a surface of the substrate by filling a liquid fluid in a reaction chamber in which the substrate is placed, and reacting a precursor solved in the liquid fluid in the vicinity of the surface of the substrate, wherein said substrate is placed on a ceiling of said reaction chamber with the surface of the substrate oriented downward.

2. The method of manufacturing a substrate according to claim 1, wherein said substrate is heated from a back side of the substrate.

3. The method of manufacturing a substrate according to claim 2, wherein heat insulation is provided between heating means for heating the substrate and an inner wall of said reaction chamber.

4. The method of manufacturing a substrate according to claim 1, wherein a flow regulation plate is disposed at a position opposite to the surface of the substrate.

5. The method of manufacturing a substrate according to claim 4, wherein a gap between the surface of the substrate and said flow regulation plate is set to 20 mm or less.

6. The method of manufacturing a substrate according to claim 5, wherein said reaction chamber is divided into a first reaction chamber and a second reaction chamber by said flow regulation plate, and said first reaction chamber is held at the same pressure as said second reaction chamber.

7. The method of manufacturing a substrate according to claim 6, wherein said liquid fluid is supplied to said second reaction chamber.

8. The method of manufacturing a substrate according to claim 1, wherein said liquid fluid is a supercritical fluid.

9. A method of manufacturing a substrate for processing a surface of the substrate by filling a liquid fluid in a reaction chamber in which the substrate is placed, and reacting a precursor solved in the liquid fluid in the vicinity of the surface of the substrate, wherein said substrate is placed in a direction in which heat rises due to a convection of the liquid fluid.

10. The method of manufacturing a substrate according to claim 9, wherein said substrate is heated from a back side of the substrate.

11. The method of manufacturing a substrate according to claim 10, wherein heat insulation is provided between heating means for heating the substrate and an inner wall of said reaction chamber.

12. The method of manufacturing a substrate according to claim 9, wherein a flow regulation plate is disposed at a position opposite to the surface of the substrate.

13. The method of manufacturing a substrate according to claim 12, wherein a gap between the surface of the substrate and said flow regulation plate is set to 20 mm or less.

14. The method of manufacturing a substrate according to claim 12, wherein said reaction chamber is divided into a first reaction chamber and a second reaction chamber by said flow regulation plate, and said first reaction chamber is held at the same pressure as said second reaction chamber.

15. The method of manufacturing a substrate according to claim 14, wherein said liquid fluid is supplied to said second reaction chamber.

16. The method of manufacturing a substrate according to claim 9, wherein said liquid fluid is a supercritical fluid.
